(19) United States
(12) Patent Application Publication
(10) Pub. No.: US 2015/0214114 A1
(43) Pub. Date: Jul. 30, 2015

(54) MANUFACTURING METHOD OF SEMICONDUCTOR STRUCTURE

(71) Applicant: United Microelectronics Corp., Hsinchu (TW)

(72) Inventors: Po-Cheng Huang, Kaohsiung City (TW); Yu-Ting Li, Chiayi City (TW); Wu-Sian Sie, Tainan City (TW); Yi-Liang Liu, Tainan City (TW); Chun-Hsiung Wang, Kaohsiung City (TW); Kun-Ju Li, Tainan City (TW); Chia-Lin Hsu, Tainan City (TW); Chih-Chien Liu, Taipei City (TW)

(73) Assignee: United Microelectronics Corp., Hsinchu (TW)

(21) Appl. No.: 14/166,091

(22) Filed: Jan. 28, 2014

(51) Int. Cl. H01L 21/8234; H01L 29/423; H01L 21/311; H01L 21/3105; H01L 29/66; H01L 21/321

(52) U.S. Cl. CPC H01L 21/823437; H01L 29/66545; H01L 21/3212; H01L 21/31111; H01L 21/31055; H01L 29/4236

(57) ABSTRACT

A manufacturing method of a semiconductor structure is disclosed. The manufacturing method includes the following steps. A substrate with a plurality of dummy gate structures formed thereon and a first dielectric layer covering the dummy gate structures is provided, the dummy gate structures comprising a plurality of dummy gates and a plurality of insulating layers formed on the dummy gates, wherein at least two of the dummy gate structures have different heights. A first planarization process is performed to expose at least one of the dummy gate structures having the highest height. A first etching process is performed to expose the insulating layers. A chemical mechanical polishing (CMP) process with a non-selectivity slurry is performed to planarize the dummy gate structures. The planarized dummy gate structures are removed to form a plurality of gate trenches.

### BACKGROUND

1. Technical Field

The disclosure relates in general to a manufacturing method of a semiconductor structure, and more particularly to a manufacturing method of a semiconductor structure with gate trenches having great height uniformity.

2. Description of the Related Art

While the size of semiconductor devices, such as metal-oxide-semiconductors (MOS), scales down, the conventional polysilicon gates have faced a variety of problems. Accordingly, work function metals along with high-K gate dielectric layers are used in the semiconductor devices for replacing the conventional polysilicon gates and being used as control electrodes. Among the current processes for replacing conventional polysilicon gates, the gate last process is one of the main processes that have been widely used.

However, despite that the gate last process is able to avoid processes of high thermal budget and to provide more material choices for the high-K gate dielectric layers and the metal gates, the gate last process still faces some problems. Therefore, there is always a continuing need in improving the semiconductor processing to develop semiconductor devices with metal gates for providing superior performance and reliability.

### SUMMARY OF THE INVENTION

The disclosure is directed to a manufacturing method of a semiconductor structure. According to some embodiments of the present disclosure, a chemical mechanical polishing process with a non-selectivity slurry is performed to planarize dummy gate structures, such that the semiconductor structure is provided with gate trenches, which are formed from removing the dummy gate structures, having great height uniformity.

According to an embodiment of the present disclosure, a manufacturing method of a semiconductor structure is disclosed. The manufacturing method includes the following steps: providing a substrate with a plurality of dummy gate structures formed thereon and a first dielectric layer covering the dummy gate structures, the dummy gate structures comprising a plurality of dummy gates and a plurality of insulating layers formed on the dummy gates, wherein at least two of the dummy gate structures have different heights; performing a first planarization process to expose at least one of the dummy gate structures having the highest height; performing a first etching process to expose the insulating layers; performing a chemical mechanical polishing (CMP) process with a non-selectivity slurry to planarize the dummy gate structures; and removing the planarized dummy gate structures to form a plurality of gate trenches.

According to another embodiment of the present disclosure, a manufacturing method of a semiconductor structure is disclosed. The manufacturing method includes the following steps: providing a substrate with a plurality of dummy gate structures formed thereon and a first dielectric layer covering the dummy gate structures, the dummy gate structures comprising a plurality of dummy gates and a plurality of insulating layers formed on the dummy gates, wherein at least two of the dummy gate structures have different heights; performing a first planarization process to expose at least one of the dummy gate structures having the highest height; removing a portion of the first dielectric layer to expose portions of the dummy gate structures; performing a chemical mechanical polishing (CMP) process with a non-selectivity slurry to planarize the dummy gate structures; and removing the planarized dummy gate structures to form a plurality of gate trenches.

The disclosure will become apparent from the following detailed description of the preferred but non-limiting embodiments. The following description is made with reference to the accompanying drawings.

### BRIEF DESCRIPTION OF THE DRAWINGS

FIGS. 1A-1H illustrate a manufacturing method of a semiconductor structure according to an embodiment of the present disclosure;

FIGS. 2A-2C illustrate a manufacturing method of a semiconductor structure according to another embodiment of the present disclosure;

FIGS. 3A-3D illustrate a manufacturing method of a semiconductor structure according to a further embodiment of the present disclosure;

FIGS. 4A-4C illustrate a manufacturing method of a semiconductor structure according to a still another embodiment of the present disclosure; and

FIGS. 5A-5D illustrate a manufacturing method of a semiconductor structure according to a still further embodiment of the present disclosure.

### DETAILED DESCRIPTION OF THE INVENTION

In some embodiments of the present disclosure, in a manufacturing method of a semiconductor structure, a chemical mechanical polishing process with a non-selectivity slurry is performed to planarize dummy gate structures, such that the semiconductor structure is provided with gate trenches, which are formed from removing the dummy gate structures, having great height uniformity. The embodiments are described in details with reference to the accompanying drawings. The procedures and details of the method of the embodiments are for exemplification only, not for limiting the scope of protection of the disclosure. Moreover, the identical elements of the embodiments are designated with the same reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense.

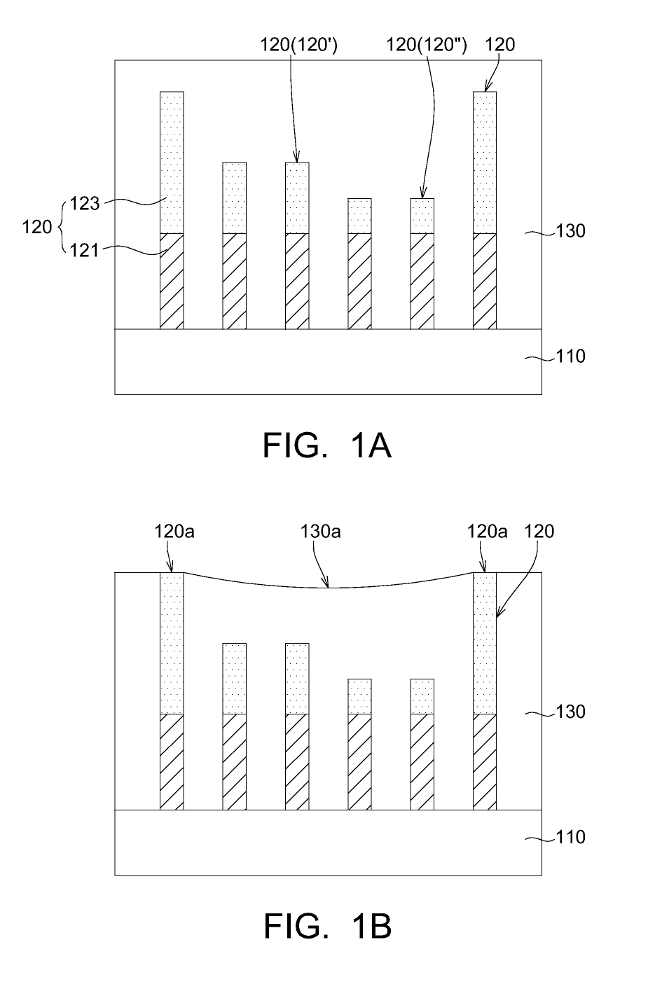

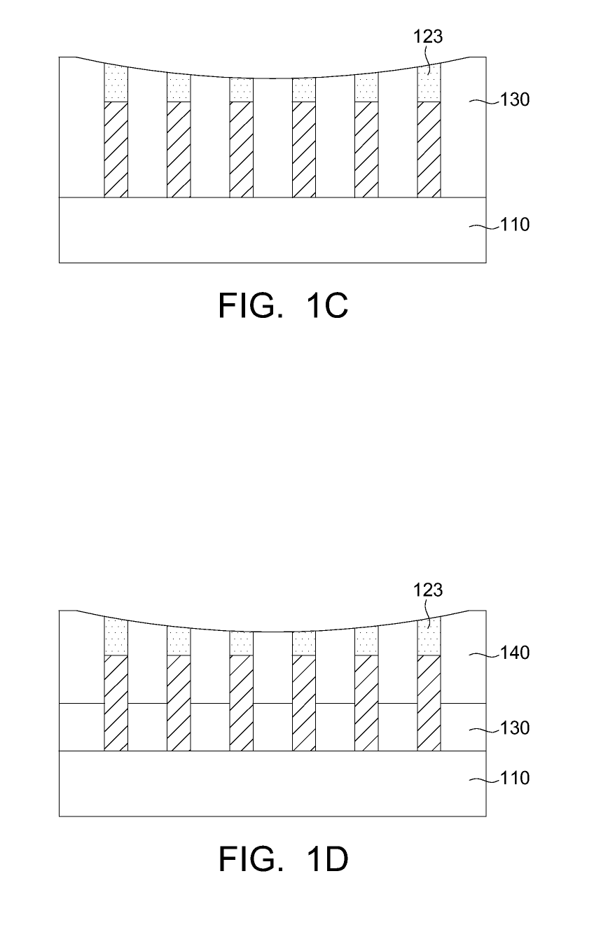

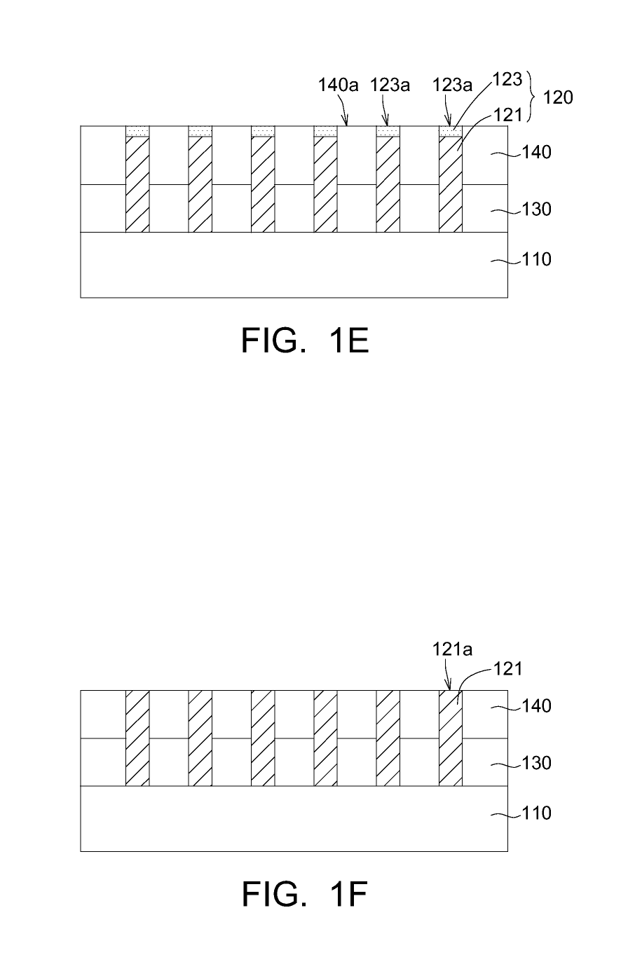

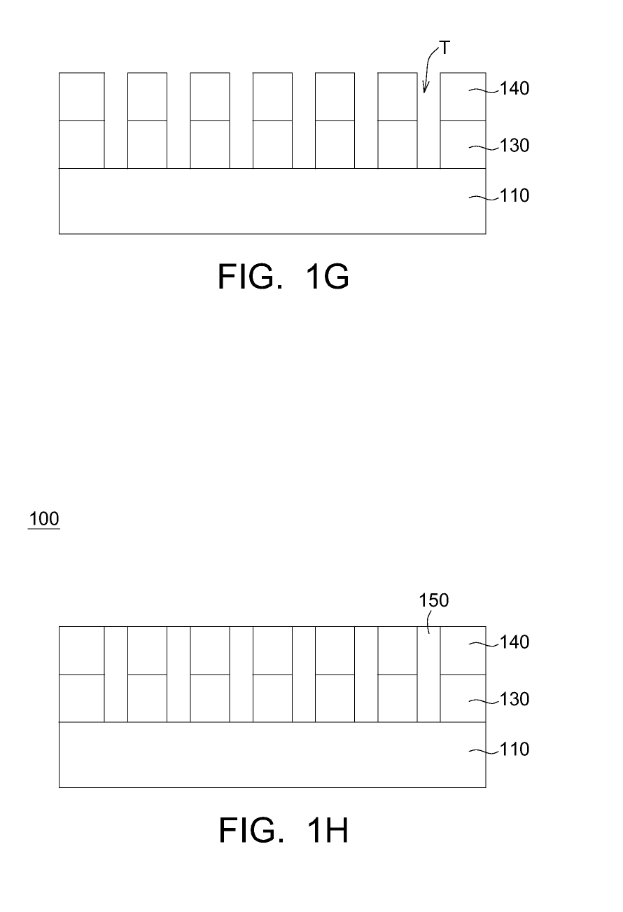

FIGS. 1A-1H illustrate a manufacturing method of a semiconductor structure 100 according to an embodiment of the present disclosure. Referring to FIG. 1A, a substrate 110 with a plurality of dummy gate structures 120 formed on the substrate 110 and a first dielectric layer 130 covering the dummy gate structures 120 is provided. As shown in FIG. 1A, the dummy gate structures 120 comprise a plurality of dummy gates 121 and a plurality of insulating layers 123 formed on the dummy gates 121, and at least two of the dummy gate structures 120 have different heights.

For example, as shown in FIG. 1A, the dummy gate structures 120 have the highest height, the dummy gate structures 120′ have the second highest height, and the dummy gate structures 120″ have the lowest height. In an embodiment, the dummy gates 121 are formed of a conductive material, such as polysilicon, the insulating layers 123 are hard masks and formed of such as silicon nitride, and the first dielectric layer 130 is formed of a dielectric material, such as flowable oxide. In the embodiment, spacers (not shown) may be further formed on two sides of the dummy gate structures 120, and a contact etch stop layer (CESL) (not shown) may be further formed on the dummy gate structures 120 and the spacers.

Referring to FIG. 1B, a first planarization process is performed to expose at least one of the dummy gate structures 120 having the highest height. In the present embodiment, as shown in FIG. 1B, the first planarization process is performed on the first dielectric layer 130 to expose the top surfaces 120a of two dummy gate structures 120 having the highest heights. That is, the first planarization process is performed on the first dielectric layer 130 until the top surface 120a of the highest dummy gate structure 120 is exposed. In the embodiment, the first planarization process is such as a chemical mechanical polishing (CMP) process with a high selectivity slurry. In other words, in the embodiment, the first planarization process is performed by a CMP process with a high selectivity slurry on the first dielectric layer 130 and stops at the top surface 120a of the dummy gate structure 120 having the highest height. Since the heights of the dummy gate structures 120 are known and can be controlled, as such, the amount of the first dielectric layer 130 removed by the first planarization process can be easily controlled.

As shown in FIG. 1B, due to the large distance between the two dummy gate structures 120 having the highest height, a CMP dishing effect may occur on the top surface 130a of the first dielectric layer 130, wherein a recess is formed within the top surface 130a of the first dielectric layer 130. That is, the first dielectric layer 130 is not fully planarized by the first planarization process due to the dummy gate structures 120 having different heights.

Referring to FIG. 10, a first etching process is performed to expose the insulating layers 123. In the present embodiment, the first etching process is performed with an etchant, and an etching selectivity of the insulating layers 123 to the first dielectric layer 130 of the etchant is about 1:1. In an embodiment, the first dielectric layer 130 is formed of such as silicon oxide, the insulating layers 123 are formed of such as silicon nitride, and the first etching process is performed with an etchant with about 1:1 oxide to nitride etching selectivity.

Referring to FIG. 1D, a portion of the first dielectric layer 130 is removed to expose portions of the dummy gate structure 120. And then, a second dielectric layer 140 is disposed on the remained first dielectric layer 130 to cover the dummy gate structures 120. Next, as shown in FIG. 1D, a second planarization process is performed to expose the insulating layers 123. In the present embodiment, the second dielectric layer 140 may be formed of a material different from that of the first dielectric layer 130, and the second dielectric layer 140 may be formed of such as a high-density plasma (HDP) oxide. In an embodiment, the first dielectric layer 130 in combination with the second dielectric layer 140 is used as an interlayer dielectric (ILD) layer. The second planarization process is such as a CMP process with a high selectivity slurry. It is to be noted that the processes as illustrated in FIG. 1D are optional in the present embodiment. That is, according to the embodiments of the present disclosure, the formation of the second dielectric layer 140 and the second planarization process performed on the second dielectric layer 140 may be omitted; in such case, the first dielectric layer 130 is used as the interlayer dielectric layer.

Referring to FIG. 1E, a chemical mechanical polishing process is performed with a non-selectivity slurry to planarize the dummy gate structures 120. As shown in FIG. 1E, in the present embodiment, the chemical mechanical polishing process is performed to remove portions of the insulating layers 123, and the exposed top surfaces 123a of the insulating layers 123 are coplanar; that is, the planarized dummy gate structures 120 include the dummy gates 121 and the insulating layers 123 with planarized top surfaces 123a. In an embodiment, the chemical mechanical polishing process is performed on the second dielectric layer 140 and after the second planarization process. Since the chemical mechanical polishing process is performed with a non-selectivity slurry, the top surfaces 123a of the insulating layers 123 and the top surface 140a of the second dielectric layer 140 all together form a flat top surface of the whole structure, as shown in FIG. 1E. As such, gate trenches which will be manufactured in the subsequent processes may have uniform heights.

Moreover, since the top surfaces of the dummy gates 121 may vary in size and shape, the dummy gates 121 having different sizes and/or shapes may suffer from different CMP loading effects. That is, the polishing rates of the dummy gates 121 may vary depending on the sizes and shapes of the top surfaces of the dummy gates 121, resulting in different polishing levels of different dummy gates 121 and non-uniformity of the top surfaces of the dummy gates 121. According to the present embodiment, the chemical mechanical polishing process is performed with a non-selectivity slurry on the second dielectric layer 140 and stops at the top surfaces 123a of the insulating layers 123, rather than stopping at the top surfaces of the dummy gates 121, the CMP loading of the dummy gates 121 can be effectively prevented, providing with a more uniform top surface of the whole structure.

Referring to FIG. 1F, after the chemical mechanical polishing process as shown in FIG. 1E, a second etching process is performed to fully remove the insulating layers 123 and expose the dummy gates 121, and the exposed top surfaces 121a of the dummy gates 121 are coplanar. In the present embodiment, the second etching process may be a dry etching process, such as a SICONI etching process. In an embodiment, the second dielectric layer 140 is formed of such as an oxide material, the insulating layers 123 are formed of such as silicon nitride, and the second etching process has a about 1:1 oxide to nitride etching selectivity. That is, in the embodiment, the second etching process is a non-selectivity etching process, which is advantageous to keeping the planarized top surface, which is formed by the chemical mechanical polishing process with a non-selectivity slurry, of the whole structure flat and uniform.

In an alternative embodiment, at least some of the processes illustrated in FIG. 1E may be emitted, and the chemical mechanical polishing process may be performed with a non-selectivity slurry to fully remove the insulating layers 123 and expose the dummy gates 121 to form the structure as shown in FIG. 1F, wherein the exposed top surfaces 121a of the dummy gates 121 are planarized and coplanar. In the present embodiment, the top surfaces 121a of the dummy gates 121 and the top surface of a dielectric layer (e.g. the first dielectric layer 130 or the second dielectric layer 140) all together form a flat top surface of the whole structure, as shown in FIG. 1E. As such, the gate trenches which will be manufactured in the subsequent processes may have uniform heights. Moreover, since the chemical mechanical polishing process is performed all the way through the insulating layers 123 and stops directly on the top surfaces 121a of the dummy gates 121, the manufacturing processes are simplified.

In summary, in the present embodiments described above, the chemical mechanical polishing process with a non-selectivity slurry may be performed directly on a dielectric layer (e.g. the first dielectric layer 130 or the second dielectric layer 140) with exposed insulating layers 123. For example, the chemically mechanical polishing process may be performed directly on the second dielectric layer 140 after the second planarization process as illustrated in FIG. 1D, or the chemical mechanical polishing process may be performed directly on the first dielectric layer 130 after the first etching process as illustrated in FIG. 1C.

Referring to FIG. 1G, the planarized dummy gate structures 120 are removed to form a plurality of gate trenches T. In the present embodiment, the planarized dummy gate structures 120 include only the planarized dummy gates 121, and the planarized dummy gates 121 are removed to form the gate trenches T. Since the top surfaces 121a of the dummy gates 121 and the top surface 140a of the second dielectric layer 140 are uniform, the gate trenches T have great height uniformity.

Referring to FIG. 1H, a plurality of metal gate structures 150 are filled in the gate trenches T. As the gate trenches T have great height uniformity, accordingly, the metal gate structures 150 have great height uniformity. In the present embodiment, the metal gate structures 150 may include at least a high-K gate dielectric layer, a work function metal, a barrier layer, and a filling metal. The metal gate structures may be formed by a replacement metal gate process. As such, the semiconductor structure 100 is formed, providing with a great within-wafer surface uniformity.

In an embodiment, the semiconductor structure 100 may be a CMOS FinFET including a NFET and a PFET, and the NFET region and the PFET region are defined by the materials of the metal gate structures 150 formed in different gate trenches T.

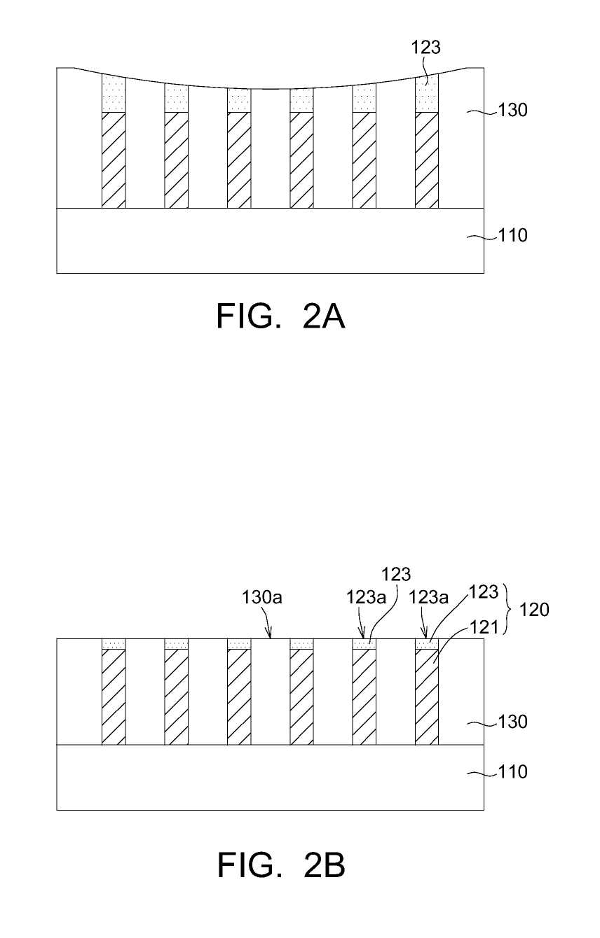

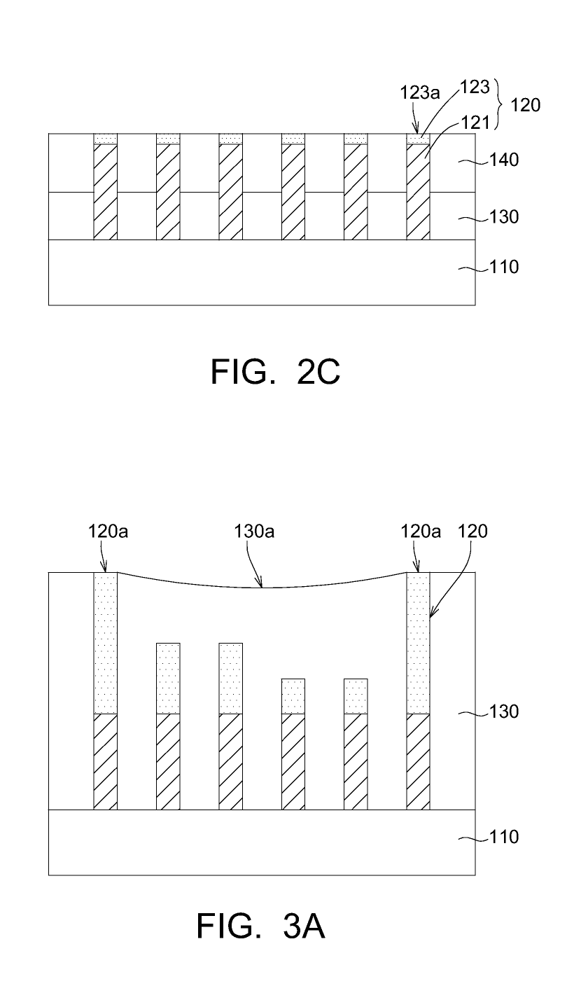

FIGS. 2A-2C illustrate a manufacturing method of a semiconductor structure according to another embodiment of the present disclosure. Referring to FIGS. 1A-1C and 2A, the first planarization process is performed to expose at least one of the dummy gate structures 120 having the highest height, and the first etching process is performed to expose the insulating layers 123.

Referring to FIG. 2B, a chemical mechanical polishing process is performed with a non-selectivity slurry to planarize the dummy gate structures 120. As shown in FIG. 2B, in the present embodiment, the chemical mechanical polishing process is performed to remove portions of the insulating layers 123, and the exposed top surfaces 123a of the insulating layers 123 are coplanar. In the present embodiment, the chemical mechanical polishing process is performed on the first dielectric layer 130. Since the chemical mechanical polishing process is performed with a non-selectivity slurry, the top surfaces 123a of the insulating layers 123 and the top surface 130a of the first dielectric layer 130 all together form a flat top surface of the whole structure, as shown in FIG. 2B. As such, gate trenches which will be manufactured in the subsequent processes may have uniform heights.

Referring to FIG. 2C, after the chemical mechanical polishing process is performed on the first dielectric layer 130, a portion of the first dielectric layer 130 is removed to expose portions of the dummy gate structure 120. And then, the second dielectric layer 140 is disposed on the remained first dielectric layer 130 to cover the dummy gate structures 120. Next, as shown in FIG. 2C, a second planarization process is performed to expose the insulating layers 123, and the second planarization process is such as a CMP process with a high selectivity slurry. In the present embodiment, the chemical mechanical polishing process is performed on the first dielectric layer 130 and before the second planarization process.

Referring to FIG. 1F, after the second planarization process as shown in FIG. 2C, the second etching process is performed to fully remove the insulating layers 123 and expose the dummy gates 121, and the exposed top surfaces 121a of the dummy gates 121 are coplanar. In the present embodiment, the second etching process is a dry etching process, such as a SICONI etching process, and the etching selectivity of the insulating layers 123 (e.g. nitride) to the second dielectric layer 140 (e.g. oxide) of the second etching process is about 1:1. That is, in the embodiment, the second etching process is a non-selectivity etching process, which is advantageous to keeping the planarized top surface, which is formed by the chemical mechanical polishing process with a non-selectivity slurry, of the whole structure flat and uniform.

Next, referring to FIG. 1G, the planarized dummy gate structures 120 (the planarized dummy gates 121) are removed to form a plurality of gate trenches T having great height uniformity. And then, metal gate structures are filled in the gate trenches T; accordingly, the metal gate structures 150 have great height uniformity. As such, the semiconductor structure 100 as shown in FIG. 1H is formed, providing with a great within-wafer surface uniformity.

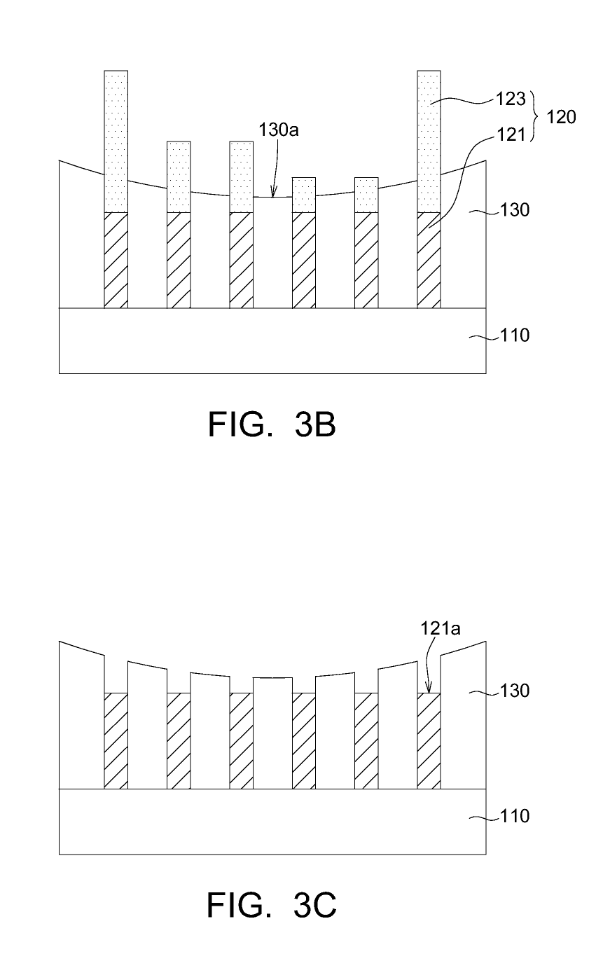

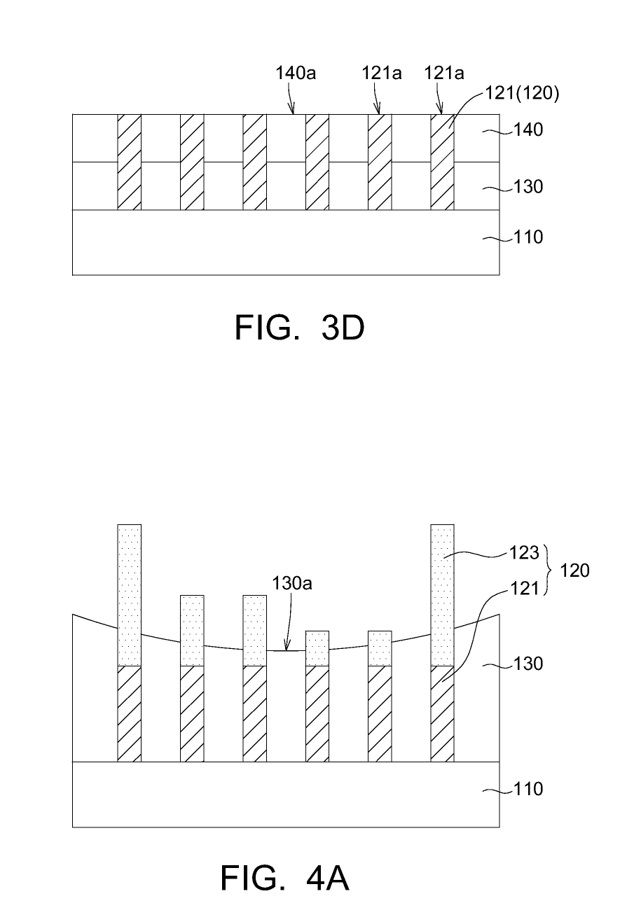

FIGS. 3A-3D illustrate a manufacturing method of a semiconductor structure according to a further embodiment of the present disclosure. Referring to FIGS. 1A-1B and 3A, the substrate 110 with the dummy gate structures 120 formed on the substrate 110 and the first dielectric layer 130 covering the dummy gate structures 120 is provided. The dummy gate structures 120 comprise the dummy gates 121 and the insulating layers 123 formed on the dummy gates 121, and at least two of the dummy gate structures 120 have different heights. As shown in FIG. 3A, the first planarization process is performed to expose at least one of the dummy gate structures 120 having the highest height. In the embodiment, the first planarization process is such as a CMP process with a high selectivity slurry.

Referring to FIG. 3B, a portion of the first dielectric layer 130 is removed to expose portions of the dummy gate structures 120. In the present embodiment, the exposed portions of the dummy gate structures 120 include insulating layers 123, and the dummy gates 121 are embedded in the remained first dielectric layer 130. In the embodiment, the portions of the first dielectric layer 130 are removed by such as performing an etching process on the first dielectric layer 130. In the embodiment, the etching process is performed with an etchant, and an etching selectivity of the first dielectric layer 130 to the insulating layers 123 of the etchant is higher than 1. That is, the etchant of the etching process has a high etching selectivity to the first dielectric layer 130. As shown in FIG. 3B, due to the large distance between the two dummy gate structures 120 having the highest height, a dishing effect may occur on the top surface 130a of the first dielectric layer 130, wherein a recess is formed within the top surface 130a of the first dielectric layer 130.

Referring to FIG. 3C, the insulating layers 130 are removed to expose the dummy gates 121 before the following chemical mechanical polishing process is performed. As shown in FIG. 3C, the top surfaces 121a of the dummy gates 121 are exposed. The insulating layers 130 may be removed by an etching process, such as a dry etching process or a wet etching process.

Referring to FIG. 3D, after the insulating layers 130 are removed, an additional portion of the first dielectric layer 130 is removed to expose the dummy gates 121, and a second dielectric layer 140 is disposed on the remained first dielectric layer 130 to cover the dummy gates 121. And then, a chemical mechanical polishing process is performed with a non-selectivity slurry to planarize the dummy gate structures 120. In the present step, since the insulating layers 123 have been removed in a previous step, the dummy gate structures 120 include only the dummy gates 121. In the present embodiment, the chemical mechanical polishing process is performed on the second dielectric layer 140 after the insulating layers 130 are removed to expose the dummy gates 121, and the exposed top surfaces 121a of the dummy gates 121 are coplanar. In other words, the top surfaces 121a of the dummy gates 121 are planarized. Since the chemical mechanical polishing process is performed with a non-selectivity slurry, the top surfaces 121a of the dummy gates 121 and the top surface 140a of the second dielectric layer 140 all together form a flat top surface of the whole structure, as shown in FIG. 3D. As such, gate trenches which will be manufactured in the subsequent processes may have uniform heights.

Next, referring to FIG. 1G, the planarized dummy gate structures 120 (the planarized dummy gates 121) are removed to form a plurality of gate trenches T having great height uniformity. And then, metal gate structures are filled in the gate trenches T; accordingly, the metal gate structures 150 have great height uniformity. As such, the semiconductor structure 100 as shown in FIG. 1H is formed, providing with a great within-wafer surface uniformity.

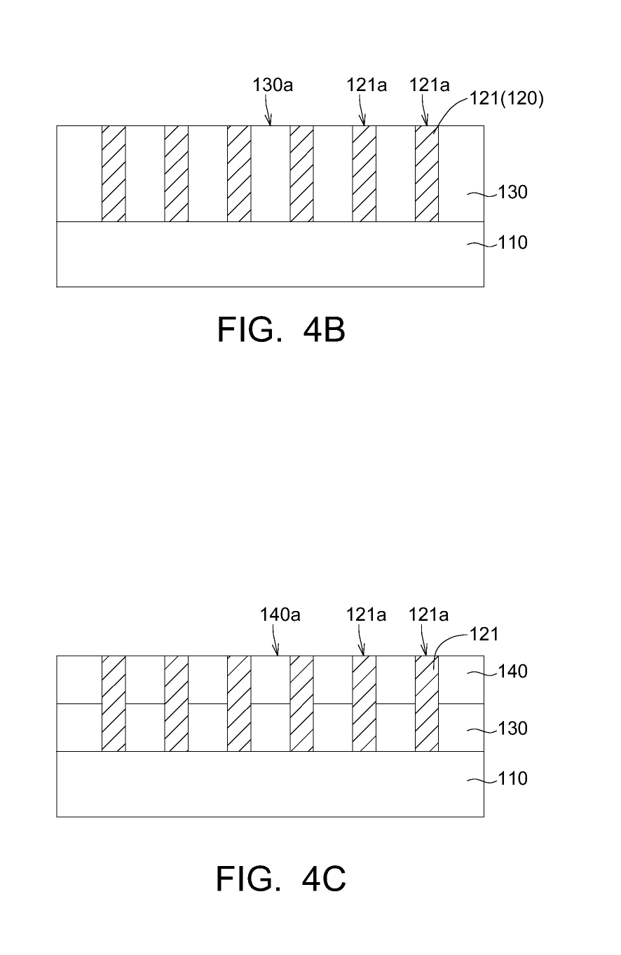

FIGS. 4A-4C illustrate a manufacturing method of a semiconductor structure according to a still another embodiment of the present disclosure. Referring to FIGS. 3A-3B and 4A, the first planarization process is performed to expose at least one of the dummy gate structures 120 having the highest height, and a portion of the first dielectric layer 130 is removed to expose portions of the dummy gate structures 120.

Referring to FIG. 4B, a chemical mechanical polishing process with a non-selectivity slurry is performed to planarize the dummy gate structures 120. As shown in FIG. 4B, the chemical mechanical polishing process is performed on the first dielectric layer 130 to fully remove the insulating layers 123 and expose the dummy gates 121, and the exposed top surfaces 121a of the dummy gates 121 are coplanar. In other words, the top surfaces 121a of the dummy gates 121 are planarized. Since the chemical mechanical polishing process is performed with a non-selectivity slurry, the top surfaces 121a of the dummy gates 121 and the top surface 130a of the first dielectric layer 130 all together form a flat top surface of the whole structure, as shown in FIG. 4B.

Referring to FIG. 4C, an additional portion of the first dielectric layer 130 is further removed to expose the dummy gates 121, a second dielectric layer 140 is disposed on the remained first dielectric layer 130 to cover the dummy gates 121, and a second planarization process is performed to expose the dummy gates 121. As shown in FIG. 4C, the top surfaces 121a of the dummy gates 121 are coplanar. In the present embodiment, the second planarization process may be a CMP process with a high selectivity slurry or a non-selectivity slurry. In an embodiment, the second planarization process is a CMP process with a non-selectivity slurry, such that it is advantageous to keeping the whole top surface, which is formed from the top surfaces 121a of the dummy gates 121 and the top surface 140a of the second dielectric layer 140, of the whole structure flat and uniform.

Next, referring to FIG. 1G, the planarized dummy gate structures 120 (the planarized dummy gates 121) are removed to form a plurality of gate trenches T having great height uniformity. And then, metal gate structures are filled in the gate trenches T; accordingly, the metal gate structures 150 have great height uniformity. As such, the semiconductor structure 100 as shown in FIG. 1H is formed, providing with a great within-wafer surface uniformity.

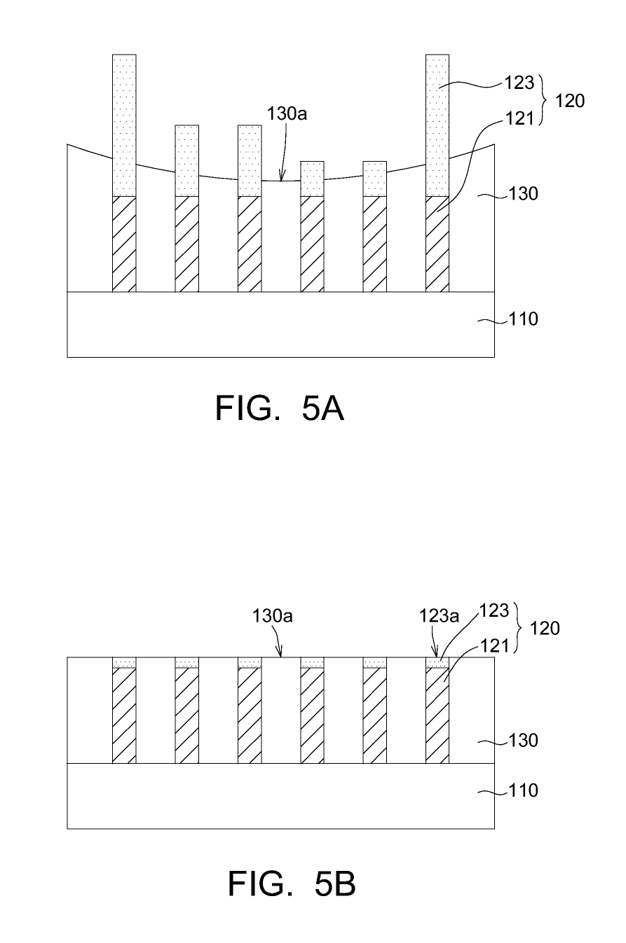

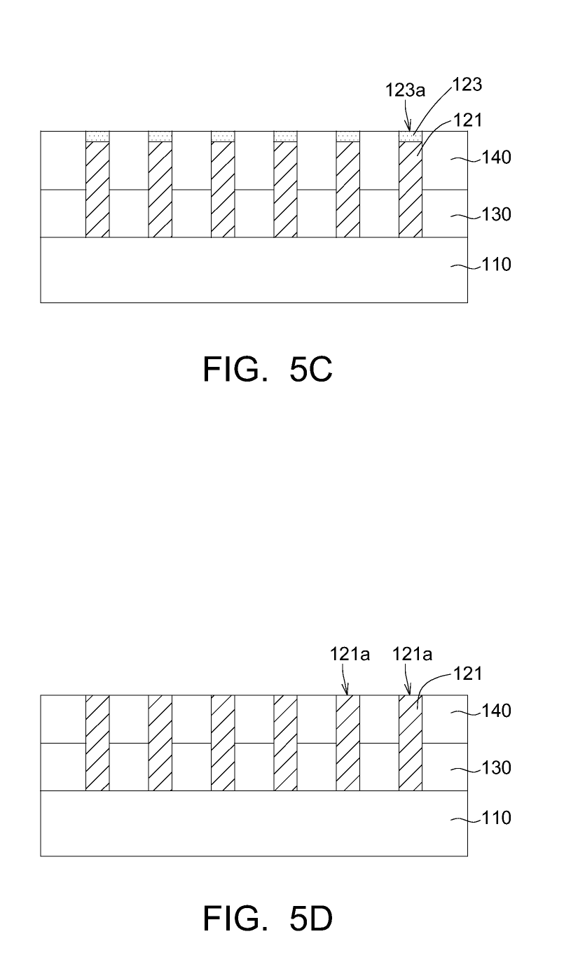

FIGS. 5A-5D illustrate a manufacturing method of a semiconductor structure according to a still further embodiment of the present disclosure. Referring to FIGS. 3A-3B and 5A, the first planarization process is performed to expose at least one of the dummy gate structures 120 having the highest height, and a portion of the first dielectric layer 130 is removed to expose portions of the dummy gate structures 120.

Referring to FIG. 5B, a chemical mechanical polishing process with a non-selectivity slurry is performed to planarize the dummy gate structures 120. As shown in FIG. 5B, the chemical mechanical polishing process is performed to remove portions of the insulating layers 123, and the exposed top surfaces 123a of the insulating layers 123 are coplanar. In the present embodiment, the chemical mechanical polishing process is performed on the first dielectric layer 130, and the top surfaces 123a of the insulating layers 123 are planarized. Since the chemical mechanical polishing process is performed with a non-selectivity slurry, the top surfaces 123a of the insulating layers 123 and the top surface 130a of the first dielectric layer 130 all together form a flat top surface of the whole structure, as shown in FIG. 5B. As such, gate trenches which will be manufactured in the subsequent processes may have uniform heights.

Referring to FIG. 5C, an additional portion of the first dielectric layer 130 is further removed to expose the insulating layers 123, a second dielectric layer 140 is disposed on the remained first dielectric layer 130 to cover the insulating layers 123, and a second planarization process is performed to expose the insulating layers 123. As shown in FIG. 5C, the top surfaces 123a of the insulating layers 123 are coplanar. In the present embodiment, the second planarization process may be a CMP process with a high selectivity slurry or a non-selectivity slurry. In an embodiment, the second planarization process is a CMP process with a non-selectivity slurry, such that it is advantageous to keeping the whole top surface, which is formed from the top surfaces 121a of the dummy gates 121 and the top surface 140a of the second dielectric layer 140, of the whole structure flat and uniform.

Referring to FIG. 5D, the insulating layers 130 are removed to expose the dummy gates 121. In the embodiment, the insulating layers 130 are removed by such as performing a second etching process to fully remove the insulating layers 123 and expose the dummy gates 121, and the exposed top surfaces 121a of the dummy gates 121 are coplanar. In the present embodiment, the second etching process is a dry etching process, such as a SICONI etching process, and the etching selectivity of the insulating layers 123 to the second dielectric layer 140 of the second etching process is about 1:1. In an embodiment, the second dielectric layer 140 is formed of such as an oxide material, the insulating layers 123 are formed of such as silicon nitride, and the second etching process has a about 1:1 oxide to nitride etching selectivity. That is, in the embodiment, the second etching process is a non-selectivity etching process, which is advantageous to keeping the planarized top surface, which is formed by the chemical mechanical polishing process with a non-selectivity slurry, of the whole structure flat and uniform. In the present embodiment, the removal of the insulating layers 123 is after performing the chemical mechanical polishing process.

Next, referring to FIG. 1G, the planarized dummy gate structures 120 (the planarized dummy gates 121) are removed to form a plurality of gate trenches T having great height uniformity. And then, metal gate structures are filled in the gate trenches T; accordingly, the metal gate structures 150 have great height uniformity. As such, the semiconductor structure 100 as shown in FIG. 1H is formed, providing with a great within-wafer surface uniformity.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a semiconductor structure, comprising:
providing a substrate with a plurality of dummy gate structures formed thereon and a first dielectric layer covering the dummy gate structures, the dummy gate structures comprising a plurality of dummy gates and a plurality of insulating layers formed on the dummy gates, wherein at least two of the dummy gate structures have different heights;
performing a first planarization process to expose at least one of the dummy gate structures having the highest height;
performing a first etching process to expose the insulating layers;
performing a chemical mechanical polishing (CMP) process with a non-selectivity slurry to planarize the dummy gate structures; and
removing the planarized dummy gate structures to form a plurality of gate trenches.

2. The manufacturing method according to claim 1, wherein the first planarization process is a CMP process with a high selectivity slurry.

3. The manufacturing method according to claim 1, wherein the first etching process is performed with an etchant with about 1:1 oxide to nitride etching selectivity.

4. The manufacturing method according to claim 1, wherein the chemical mechanical polishing process is performed to remove portions of the insulating layers, and exposed top surfaces of the insulating layers are coplanar.

5. The manufacturing method according to claim 1, further comprising:
performing a second etching process after the chemical mechanical polishing process to fully remove the insulating layers and expose the dummy gates, wherein exposed top surfaces of the dummy gates are coplanar.

6. The manufacturing method according to claim 1, wherein the chemical mechanical polishing process is performed to fully remove the insulating layers and expose the dummy gates, wherein exposed top surfaces of the dummy gates are coplanar.

7. The manufacturing method according to claim 1, further comprising:
removing a portion of the first dielectric layer to expose portions of the dummy gate structures;
disposing a second dielectric layer on the remained first dielectric layer to cover the dummy gate structures; and
performing a second planarization process to expose the insulating layers.

8. The manufacturing method according to claim 1, wherein the chemical mechanical polishing process is performed on the second dielectric layer and after the second planarization process.

9. The manufacturing method according to claim 1, wherein the chemical mechanical polishing process is performed on the first dielectric layer and before the second planarization process.

10. The manufacturing method according to claim 1, further comprising:
filling a plurality of metal gate structures in the gate trenches.

11. A manufacturing method of a semiconductor structure, comprising:
providing a substrate with a plurality of dummy gate structures formed thereon and a first dielectric layer covering the dummy gate structures, the dummy gate structures comprising a plurality of dummy gates and a plurality of insulating layers formed on the dummy gates, wherein at least two of the dummy gate structures have different heights;
performing a first planarization process to expose at least one of the dummy gate structures having the highest height;
removing a portion of the first dielectric layer to expose portions of the dummy gate structures;
performing a chemical mechanical polishing (CMP) process with a non-selectivity slurry to planarize the dummy gate structures; and
removing the planarized dummy gate structures to form a plurality of gate trenches.

12. The manufacturing method according to claim 11, wherein the first planarization process is a CMP process with a high selectivity slurry

13. The manufacturing method according to claim 11, wherein removing the portion of the first dielectric layer comprises:
performing an etching process on the first dielectric layer.

14. The manufacturing method according to claim 11, further comprising:
removing the insulating layers to expose the dummy gates before or after the chemical mechanical polishing process is performed.

15. The manufacturing method according to claim 11, wherein after removing the insulating layers, the manufacturing process further comprises:
removing an additional portion of the first dielectric layer to expose the dummy gates; and
disposing a second dielectric layer on the remained first dielectric layer to cover the dummy gates.

16. The manufacturing method according to claim 11, wherein the chemical mechanical polishing process is performed on the second dielectric layer after removing the insulating layers to expose the dummy gates, and exposed top surfaces of the dummy gates are coplanar.

17. The manufacturing method according to claim 11, wherein the chemical mechanical polishing process is performed to fully remove the insulating layers and expose the dummy gates, and exposed top surfaces of the dummy gates are coplanar.

18. The manufacturing method according to claim 11, further comprising:
removing an additional portion of the first dielectric layer to expose the dummy gates;
disposing a second dielectric layer on the remained first dielectric layer to cover the dummy gates; and
performing a second planarization process to expose the dummy gates.

19. The manufacturing method according to claim 11, wherein the chemical mechanical polishing process is performed to remove portions of the insulating layers, and exposed top surfaces of the insulating layers are coplanar.

20. The manufacturing method according to claim 11, further comprising:
removing an additional portion of the first dielectric layer to expose the insulating layers;
disposing a second dielectric layer on the remained first dielectric layer to cover the insulating layers; and
performing a second planarization process to expose the insulating layers.
